(19) United States
(12) Patent Application Publication
(10) Pub. No.: US 2022/0329047 A1
(43) Pub. Date: Oct. 13, 2022

(54) Surface Emitting Laser and Method for Manufacturing the Same

(71) Applicant: Nippon Telegraph and Telephone Corporation, Tokyo (JP)

(72) Inventors: Yoshitaka Oiso, Tokyo (JP); Tomonari Sato, Tokyo (JP)

(21) Appl. No.: 17/632,929

(22) PCT Filed: Aug. 26, 2019
(86) PCT No.: PCT/JP2019/033230

§ 371 Date: Feb. 4, 2022

(51) Int. Cl. H01S 5/183; H01S 5/20

(52) U.S. Cl. CPC H01S 5/18347; H01S 5/18377; H01S 5/2081

(57) ABSTRACT

A columnar portion is formed by etching parts of an active layer and a first reflective layer. In this etching process, the columnar portion is formed by etching the first reflective layer to a position of a semiconductor layer. For example, it is etched to a thickness of approximately 3 μm.

### CROSS-REFERENCE TO RELATED APPLICATIONS

This application is a national phase entry of PCT Application No. PCT/JP2019/033230, filed on Aug. 26, 2019, which application is hereby incorporated herein by reference.

### TECHNICAL FIELD

The present invention relates to a surface emitting laser and a method for producing the surface emitting layer.

### BACKGROUND

The introduction of surface emitting lasers (VCSELs) into face recognition systems has dramatically increased public awareness, but surface emitting lasers have traditionally been used in a wide range of applications such as short-range data transmission, laser mice, and the like. However, surface emitting lasers applied in this area are composed of a so-called GaAs-based compound semiconductor which is epitaxially grown on a GaAs substrate, and has an oscillation wavelength of 650 to 980 nm. A surface emitting laser is a current confined structure which narrows a light emitting region. An easily oxidizable layer (NPL 1) such as AlAs is inserted directly over a light emitting layer (an active layer), a mesa is formed after crystal growth, selective oxidation of the AlAs layer is performed in a lateral direction using water vapor, and thus a current path is narrowed to determine an emission diameter.

On the other hand, a surface emitting laser having a long wavelength band is composed of an InP-based compound semiconductor from the viewpoint of a band gap of the active layer, and the substrate is often limited to InP. In this case, there is no suitable material for a selective oxidation layer which lattice-matches with InP, and in many cases, a structure in which a tunnel junction is partially left and the other portions are current-blocked is adopted (NPL 2). In this technique, a reverse breakdown voltage of the pn junction is realized by leaving, etching, re-growing, and embedding a portion of a current path region which constitutes the tunnel junction, and thus a current flows only in a portion directly above the light emitting region.

### CITATION LIST

### Non Patent Literature

NPL 1: Y. Feng, et al., “High-Speed Oxidation-confined 850 nm VCSELs”, IEEE International Conference on Optoelectronics and Microelectronics, 15774293, pp. 16 to 18, 2015.

NPL 2: M.-R. Park et al., “All-Epitaxial InAlGaAs—InP VCSELs in the 1.3-1.6-μm Wavelength Range for CWDM Band Applications”, IEEE Photonics Technology Letters, vol. 18, no. 16, pp. 1717-1719, 2006.

NPL 3: Y. Ohiso et al., “1.55-μm Buried-Heterostructure VCSELs With InGaAsP/InP—GaAs/AlAs DBRs on a GaAs Substrate”, IEEE Journal of Quantum Electronics, vol. 37, no. 9, pp. 1194-1020, 2001.

### SUMMARY

### Technical Problem

As described above, for determining the light emitting portion of a surface emitting laser, an example of adopting a current confined structure is common. However, as examples of application of a surface emitting laser has become widespread, the requirements for such devices are different. For example, when it is limited to communication applications with an oscillation wavelength of 1.3 μm or more, the device is for long-distance transmission, a single lateral mode and high light output operation are most important. On the other hand, in the case of sensing applications, a plurality of elements are two-dimensionally arranged on the same substrate, and it is important that variation in characteristics between the elements is small.

In order to solve the above problems, it is considered that a structure (an embedded structure) in which the periphery of the active layer is embedded with an embedded layer is effective, and the structure is generally adopted as a waveguide type structure of a semiconductor laser. This is because, in this structure, a refractive index waveguide type in which a difference in a refractive index is provided in a lateral direction of the active layer (laterally) is provided, and the stable lateral mode operation is possible. In addition, because semiconductors are lattice-matched with each other, this structure has an advantage that the difference in the refractive index between the active layer and the embedded layer is small, and an emission diameter under single mode conditions of the lateral mode can be large (NPL 3). Accordingly, since the light emitting region under the single mode operating condition is larger than that in the conventional one, an increase in a light output can be expected in the embedded structure.

However, in order to realize an embedded structure, a predetermined region including a portion of the active layer is formed in a columnar shape by etching, and the embedded layer is then re-grown around the columnar portion. During this re-growth, because the deepest portion of the etching reaches a lower reflective layer having a distributed Bragg reflector (DBR) structure, a re-grown surface other than the columnar portion may often be a layer in the middle of the lower reflective layer under the active layer. For example, a semiconductor material constituting the reflective layer having a low refractive index is InP, InAlAs, and AlGaSb. Further, a semiconductor material constituting the reflective layer having a high refractive index is InAlGaAs, InGaAsP, AlGaSb, and the like.

For example, in a case in which the embedded structure is applied to the structure of NPL 2, a surface immediately after the etching process when the columnar portion is formed is a layer in the middle of a InAlGaAs layer or a InP layer which is alternately laminated. Here, as described above, although a plurality of elements are formed on the same substrate, an etching amount (an etching depth) in the above-described etching is generally distributed within a surface of a substrate according to performance of an etching device, and varies by about 20%.

For example, in an etching process having a thickness of 3 μm or more, in the case of a reflective layer having a DBR structure having a layer thickness of 1.3 μm to 2.0 μm, a difference of one set (a thickness of about 0.2 μm) or more of compound semiconductor layers having different refractive indexes, which are alternately laminated, will occur in the same substrate surface.

As a result, for example, a step corresponding to a layer thicknesses of one or more sets may occur at a boundary between regions in which the etching amounts are different from each other, and when the embedded layer is grown, facet growth larger than a portion of the step occurs, and a portion affected by the facet growth greatly reduces a yield.

In addition, due to the variation as described above, a height of the surface on which the embedded layer is grown from the substrate is different among the plurality of elements formed on the same substrate. For example, when the embedded structure is a pn embedded structure, a position of an n layer of a current block layer varies depending on the inside of the substrate surface, and a thickness of a leak path in the vicinity of the active layer of the columnar portion varies between the elements, causing a difference in the leak current, and element characteristics become significantly different. In addition, the steps between the embedded layer and an upper portion of the columnar portion are different from each other between the elements on the same substrate (in-plane), and there is a problem that facets are likely to occur in the process after the embedded layer is formed or in the crystal growth when an upper mirror layer is formed.

Embodiments of the present invention have been made to solve the above problems, and an object of embodiments of the present invention is to suppress variation between the elements and the like and to produce a plurality of surface emitting laser elements on the same substrate.

### Means for Solving the Problem

A method for producing a surface emitting laser according to embodiments of the present invention includes: a first step of forming a first reflective layer having a distributed Bragg reflector structure, in which compound semiconductor layers each having a different refractive index are alternately laminated, on a substrate, a second step of forming an active layer formed of a compound semiconductor on the first reflective layer, a third step of forming a columnar portion by etching the active layer and a part of the first reflective layer, a fourth step of embedding the columnar portion by forming an embedded layer on the first reflective layer around the columnar portion, and a fifth step of forming a second reflective layer having a distributed Bragg reflector structure, in which compound semiconductor layers each having a different refractive index are alternately laminated, on the columnar portion and the embedded layer, wherein the first reflective layer has a semiconductor layer having a thickness which is an odd multiple of 1/(4nλ), and in the third step, the columnar portion is formed by etching the first reflective layer to a position of the semiconductor layer.

A surface emitting laser according to embodiments of the present invention includes: a first reflective layer formed on a substrate and having a distributed Bragg reflector structure in which compound semiconductor layers each having a different refractive index are alternately laminated, a columnar portion formed on the first reflective layer, an active layer formed on the first reflective layer of the columnar portion and formed of a compound semiconductor, an embedded layer formed on the first reflective layer around the columnar portion and configured to embed the active layer and the first reflective layer of the columnar portion, and a second reflective layer formed on the columnar portion and the embedded layer and having a distributed Bragg reflector structure in which compound semiconductor layers each having a different refractive index are alternately laminated, wherein the first reflective layer near a lowermost portion of the columnar portion has a semiconductor layer having a thickness which is an odd multiple of 1/(4nλ).

### Effects of Embodiments of the Invention

As described above, according to embodiments of the present invention, because a semiconductor layer having a thickness which is an odd multiple of 1/(4nλ) is provided in the first reflective layer, and the first reflective layer is etched to a position of a semiconductor layer to form a columnar portion, variations between elements and the like can be curbed, and a plurality of surface emitting laser elements can be produced on the same substrate.

### BRIEF DESCRIPTION OF THE DRAWINGS

FIG. 1A is a cross-sectional view illustrating a state of each of layers in an intermediate process for explaining a method for producing a surface emitting laser according to an embodiment of the present invention.

FIG. 1B is a cross-sectional view illustrating the state of each of layers in the intermediate process for explaining the method for producing a surface emitting laser according to the embodiment of the present invention.

FIG. 1C is a cross-sectional view illustrating the state of each of layers in the intermediate process for explaining the method for producing a surface emitting laser according to the embodiment of the present invention.

FIG. 1D is a cross-sectional view illustrating the state of each of layers in the intermediate process for explaining the method for producing a surface emitting laser according to the embodiment of the present invention.

FIG. 1E is a cross-sectional view illustrating the state of each of layers in the intermediate process for explaining the method for producing a surface emitting laser according to the embodiment of the present invention.

FIG. 1F is a cross-sectional view illustrating the state of each of layers in the intermediate process for explaining the method for producing a surface emitting laser according to the embodiment of the present invention.

FIG. 2 is a characteristics diagram illustrating characteristics of the surface emitting laser actually produced.

### DETAILED DESCRIPTION OF ILLUSTRATIVE EMBODIMENTS

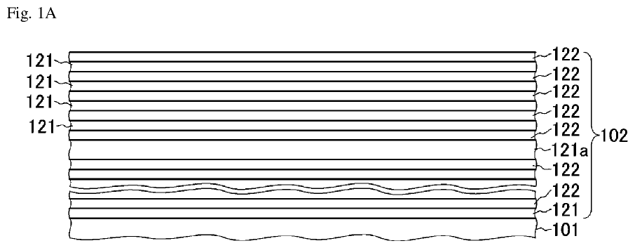

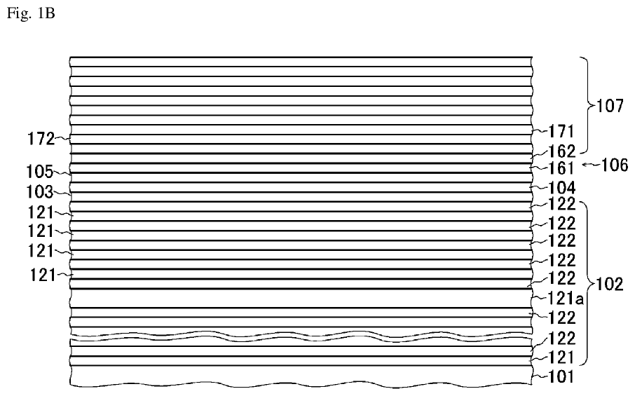

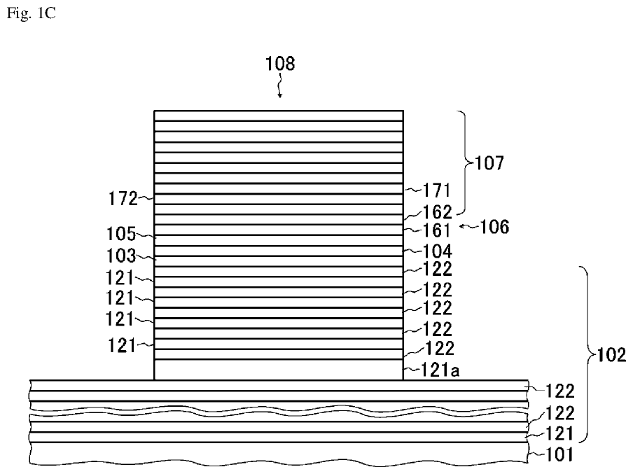

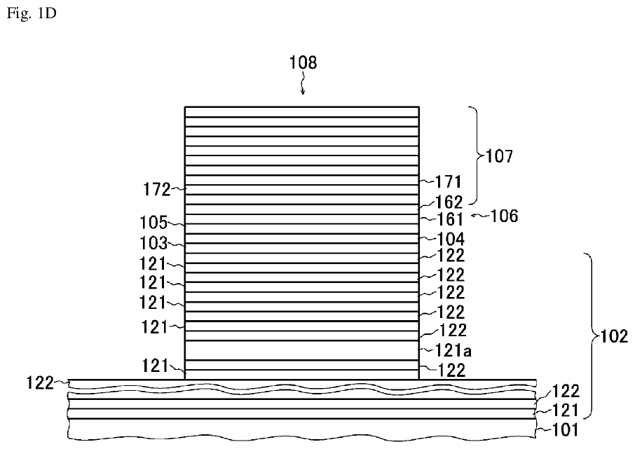

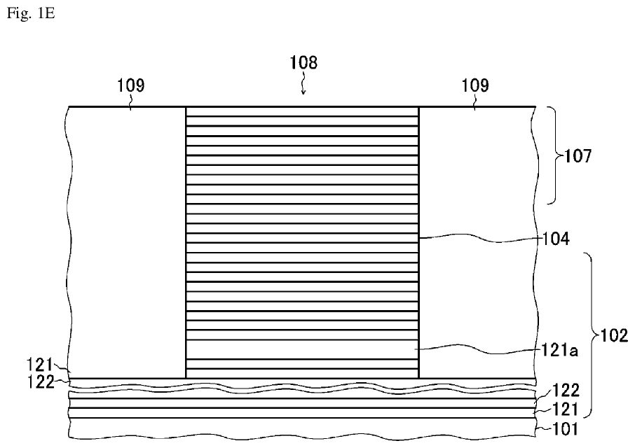

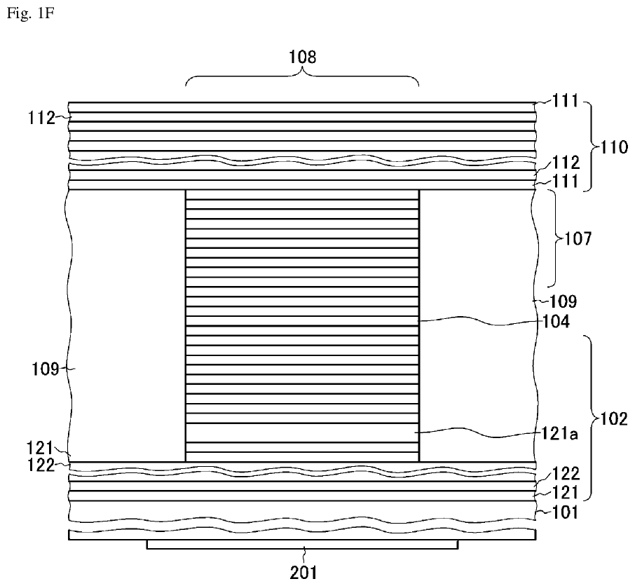

Hereinafter, a method for producing a surface emitting laser according to an embodiment of the present invention will be described with reference to FIGS. 1A to 1F.

First, as illustrated in FIG. 1A, a first reflective layer 102 having a distributed Bragg reflector (DBR) structure in which compound semiconductor layers having different refractive indices are alternately laminated is formed on a substrate 101 (a first step). The first reflective layer 102 has a semiconductor layer 121a having a thickness which is an odd multiple of 1/(4nλ). λ is a wavelength (an oscillation wavelength) of target light. The substrate 101 is composed of, for example, an n type InP. In addition, the first reflective layer 102 has a superlattice structure in which, for example, 54 sets of n-InP layers 121 formed of an n type InP and n-InAlGaAs layers 122 formed of an n type InAlGaAs are alternately laminated. In this example, one of the n-InP layers 121 is the semiconductor layer 121a. The first reflective layer 102 having the above-described configuration serves as a semi-reflective layer.

Next, as illustrated in FIG. 1B, an active layer 104 formed of a compound semiconductor is formed the first reflective layer 102 (a second step). For example, an active layer 104 is formed on the first reflective layer 102 via a spacer layer 103 formed of the n type InP. Further, a spacer layer 105 formed of a p type InP is formed on the active layer 104. Also, in the present embodiment, a tunnel junction layer 106 is formed on the spacer layer 105 (a sixth step). The tunnel junction layer 106 is composed of a pn junction of a p⁺⁺-InP layer 161 formed of InP into which p-type impurities are introduced in a high concentration, and an n⁺⁺-InP layer 162 formed of InP into which n-type impurities are introduced in a high concentration.

Further, in the present embodiment, a laminated structure 107 in which five sets of an n-InP layer 171 formed of an n type InP and an n-InAlGaAs layer 172 formed of an n type InAlGaAs are laminated on the tunnel junction layer 106 is provided. The laminated structure 107 is a distributed Bragg reflector layer having a superlattice structure.

Each of the above-described semiconductor layers is formed by crystal growth (epitaxial growth) using a well-known metalorganic vapor phase growth method, molecular beam epitaxy method, or the like.

Next, parts of the active layer 104 and the first reflective layer 102 are etched to form a columnar portion 108 (a third step), as illustrated in FIG. 1C. In the present embodiment, the columnar portion 108 is formed by patterning due to an etching process using a SiO₂ pattern (not illustrated) formed of SiO₂ as a mask. First, SiO₂ is deposited on the laminated structure 107 by a known chemical vapor deposition (CVD) method, for example, to form a SiO₂ layer. Then, the SiO₂ pattern can be formed by patterning the SiO₂ layer due to the etching process using a known lithographic and RIE device.

Next, the columnar portion 108 is formed by etching the laminated structure 107, the tunnel junction layer 106, the spacer layer 105, the active layer 104, the spacer layer 103, and a part of the first reflective layer 102 due to ICP dry etching using a mixed gas of hydrogen iodide (HI) and argon (Ar) with the formed SiO₂ pattern as a mask. Although one columnar portion 108 is illustrated in the drawing, a plurality of columnar portions 108 are formed on a substrate 101 in another region not illustrated in the drawings in a state in which each of them is separated in a surface direction of the substrate 101.

In the etching process, the first reflective layer 102 is etched to a position of the semiconductor layer 121a to form the columnar portion 108. In the present embodiment, for example, the etching is performed to a thickness of about 3 μm. For example, in a typical etching treatment device which performs the above-described etching, due to a variation in etching in a surface of the substrate 101, an etching amount is the smallest in the center of the substrate 101, and the etching amount tends to increase toward the outer periphery, and for example, a variation in an etching depth is within about 7%.

In this case, the fifth set of the n-InP layer 121 from an upper end of the first reflective layer 102 can be set as the semiconductor layer 121a, and a thickness thereof can be set to 3/(4nλ). In this example, 3/(4nλ) corresponds to approximately 0.3 μm. A thickness of the semiconductor layer 121a having a thickness which is an odd multiple of 1/(4nλ) is set appropriately according to characteristics (the variation in the etching amount) of an environment (device) in which the etching process for forming the columnar portion 108 is performed. Because the thickness of the semiconductor layer 121a is an odd multiple of 1/(4nλ), the characteristics (reflection characteristics) of the first reflective layer 102 are not affected.

When the etching process is performed by an etching device having the above-described variation, and the etching is stopped at a location on the center portion of the substrate 101 at which the uppermost portion of the semiconductor layer ma appears (is exposed), the semiconductor layer 121a is removed at the outer peripheral portion of the substrate 101, and the n-InAlGaAs layer 122 which is located therebelow is exposed.

As described above, in order to eliminate a condition in which a different layer is exposed on the substrate 101, first, the etching process under conditions in which InP is selectively etched with respect to InAlGaAs is performed, and the semiconductor layer 121a exposed in a region forming an embedded layer other than the columnar portion 108 is removed. For example, the semiconductor layer ma formed of InP can be selectively removed by the etching process using an aqueous solution obtained by mixing HCl, H₃PO₄, and CH₃COOH as an etching solution. In this etching process, the etching is automatically stopped at the n-InAlGaAs layer 122 below the semiconductor layer 121a, and the n-InAlGaAs layer 122 below the semiconductor layer 121a is exposed in the entire region of the substrate 101. In this way, in each of the plurality of formed columnar portions 108, a layer formed of the same semiconductor is exposed at the surface of the surrounding first reflective layer 102.

In the present embodiment, in order to use InP as a surface on which the embedded layer is re-grown, following the above-described process, an etching process under a condition in which InAlGaAs is selectively etched with respect to InP is performed, and the n-InAlGaAs layer 122 exposed in the region forming the embedded layer other than the columnar portion 108 is selectively removed. For example, the n-InAlGaAs layer 122 can be selectively removed by an etching process using an aqueous solution in which H₂SO₄ and H₂O₂ are mixed as an etching solution. In this etching process, the etching is automatically stopped at the n-InP layer 121, and the n-InP layer 121 is exposed in the entire region of the substrate 101. In a state in which the n-InP layer 121 is exposed, this can be visually confirmed due to a change in a color, or the like.

Next, as illustrated in FIG. 1E, an embedded layer 109 is formed on the first reflective layer 102 around the columnar portion 108 to embed the columnar portion 108 (a fourth step). For example, the embedded layer 109 can be formed by re-growing InP from the n-InP layer 121 of the first reflective layer 102 around the columnar portion 108 which is exposed as described above using the above-described SiO₂ pattern as a selective growth mask. The embedded layer 109 can be a pn embedded structure. In addition, the embedded layer 109 is formed to form a current path.

Next, as illustrated in FIG. 1F, a second reflective layer no having a distributed Bragg reflector structure in which compound semiconductor layers having different refractive indices are alternately laminated is formed on the columnar portion 108 and the embedded layer 109 (a fifth step). After the above-described SiO₂ pattern is removed, for example, a GaAs layer 111 formed of GaAs and a AlGaAs layer 112 formed of AlGaAs are alternately grown by metamorphic growth to form the second reflective layer no. The second reflective layer no having the above-described configuration is a total reflective layer. Thus, in the present embodiment, the first reflective layer 102 and the second reflective layer no constitute a resonator, and laser is emitted from the side of the first reflective layer 102.

Further, after the second reflective layer no is formed, an upper electrode (not illustrated) and a lower electrode (not illustrated) are formed, and separation between elements is performed. The separation between elements is performed by an etching process using, for example, hydrogen bromide (HBr) as an etching solution. Furthermore, an anti-reflective layer 201 is formed on the back surface of the substrate 101.

As described above, a surface emitting laser is obtained, the surface emitting laser including a first reflective layer 102, a columnar portion 108, an active layer 104, an embedded layer 109, and a second reflective layer no. The first reflective layer 102 is formed on a substrate 101 and has a distributed Bragg reflector structure in which compound semiconductor layers each having a different refractive index are alternately laminated. The columnar portion 108 is formed on the first reflective layer 102. The active layer 104 is formed on the first reflective layer 102 of the columnar portion 108 and formed of a compound semiconductor. The embedded layer 109 is formed on the first reflective layer 102 around the columnar portion 108 and configured to embed the active layer 104 and the first reflective layer 102 of the columnar portion 108. The second reflective layer no is formed on the columnar portion 108 and the embedded layer 109 and has a distributed Bragg reflector structure in which compound semiconductor layers each having a different refractive index are alternately laminated. The first reflective layer 102 near a lowermost portion of the columnar portion 108 has a semiconductor layer 121a having a thickness which is an odd multiple of 1/(4nλ).

The surface emitting laser further includes a tunnel junction layer 106 formed by a pn junction formed on the active layer 104, the embedded layer 109 embeds the tunnel junction layer 106, the active layer 104, and the first reflective layer 102 of the columnar portion 108, and the second reflective layer no is formed on the tunnel junction layer 106. Additionally, a plurality of the columnar portions 108 are formed.

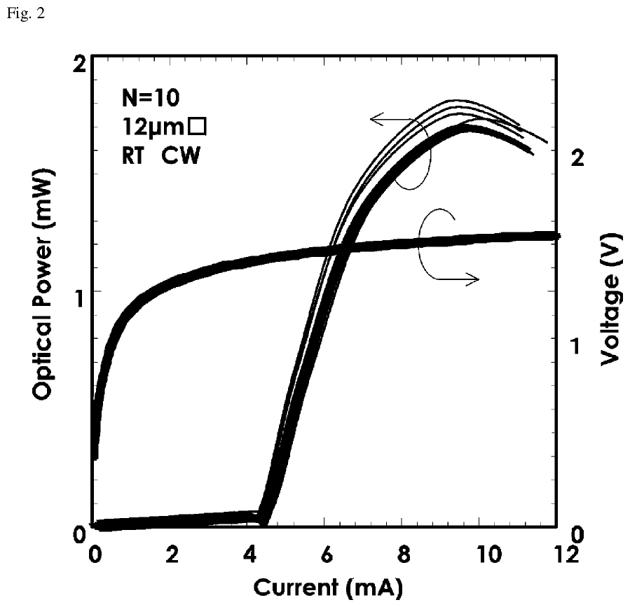

Next, evaluation results of characteristics of an actually produced surface emitting laser according to the present embodiment will be described. In the evaluation of the characteristics, the produced surface emitting laser is mounted with the second reflective layer no side down and is cooled from the second reflective layer no side, and laser light emitted from the substrate 101 side via the anti-reflective layer 201 is measured. In addition, the surface emitting laser actually produced includes 10 columnar portions (elements) on the same substrate. FIG. 2 illustrates s a relationship between a current and a voltage of the surface emitting laser, and a relationship between the current and the light characteristics. As illustrated in FIG. 2, according to the present embodiment, laser oscillation in a single lateral mode having a large emission diameter of 12 μm square is observed with characteristics that oscillation threshold variation is small between the elements and maximum light outputs are approximately the same.

As described above, according to embodiments of the present invention, because a semiconductor layer having a thickness which is an odd multiple of 1/(4nλ) is provided on the first reflective layer, and the first reflective layer is etched to the position of the semiconductor layer to form the columnar portion, variations between elements and the like can be curbed, and a plurality of surface emitting laser elements can be produced on the same substrate.

Meanwhile, the present invention is not limited to the embodiment described above, and it will be obvious to those skilled in the art that various modifications and combinations can be implemented within the technical idea of the present invention. For example, in the above description, although the surface emitting laser produced using the InP substrate has been described as an example, the present invention is not limited thereto, and the same applies to a surface emitting laser having a DBR reflective layer formed of GaAs/AlGaAs having an oscillation wavelength of 0.98 μm, which is produced using a GaAs substrate.

### REFERENCE SIGNS LIST

101 Substrate

102 First reflective layer

103 Spacer layer

104 Active layer

105 Spacer layer

106 Tunnel junction layer

107 Laminated structure

108 Columnar portion

109 Embedded layer

110 Second reflective layer

111 GaAs Layer

112 AlGaAs Layer

121 n-InP layer

121a Semiconductor layer

122 n-InAlGaAs Layer

161 p⁺⁺-InP layer

162 n⁺⁺-InP layer

171 n-InP layer

172 n-InAlGaAs Layer

201 Anti-reflective layer.

1-6. (canceled)

7. A method for producing a surface emitting laser, the method comprising:
forming, on a substrate, a first reflective layer having a distributed Bragg reflector structure in which a plurality of compound semiconductor materials each having a different refractive index are alternately laminated;
forming, on the first reflective layer, an active layer formed of a compound semiconductor;
forming a columnar portion by etching the active layer and a part of the first reflective layer;
embedding the columnar portion by forming an embedded layer on the first reflective layer around the columnar portion; and
forming, on the columnar portion and the embedded layer, a second reflective layer having a distributed Bragg reflector structure in which the plurality of compound semiconductor materials each having a different refractive index are alternately layered, wherein the first reflective layer has a semiconductor layer having a thickness which is an odd multiple of 1/(4nλ), wherein λ is a wavelength of target light, wherein n is a positive integer, and wherein in forming of the columnar portion, the columnar portion is formed by etching the first reflective layer to a position of the semiconductor layer.

8. The method for producing a surface emitting laser according to claim 7, the method further comprising:
forming, on the active layer, a tunnel junction layer as a pn junction;
wherein in forming of the columnar portion, the columnar portion is formed by etching the tunnel junction layer, the active layer, and the first reflective layer.

9. The method for producing a surface emitting laser according to claim 7, wherein, in forming of the columnar portion, a plurality of the columnar portions are formed and a layer formed of a same semiconductor is exposed on a surface of the first reflective layer around the columnar portion.

10. A surface emitting laser comprising:
a first reflective layer having a distributed Bragg reflector structure in which a plurality of compound semiconductor materials each having a different refractive index are alternately disposed, the first reflective layer being disposed on a substrate;
a columnar portion on the first reflective layer;
an active layer comprising a compound semiconductor, the active layer being disposed on the first reflective layer of the columnar portion;
an embedded layer on the first reflective layer around the columnar portion, the embedded layer embedding the active layer and the first reflective layer of the columnar portion; and
a second reflective layer having a distributed Bragg reflector structure in which compound semiconductor layers each having a different refractive index are alternately disposed, the second reflective layer being disposed on the columnar portion and the embedded layer, wherein the first reflective layer near a lowermost portion of the columnar portion has a semiconductor layer having a thickness which is an odd multiple of 1/(4nλ), wherein λ is a wavelength of target light, and wherein n is a positive integer.

11. The surface emitting laser according to claim 10, further comprising a tunnel junction layer comprising a pn junction on the active layer, wherein the embedded layer embeds the tunnel junction layer, the active layer, and the first reflective layer of the columnar portion, and wherein the second reflective layer is disposed on the tunnel junction layer.

12. The surface emitting laser according to claim 10 further comprising a plurality of columnar portions, the plurality of columnar portions comprising the columnar portion.
